(19) United States
(12) Patent Application Publication
(10) Pub. No.: US 2005/0281985 A1
(43) Pub. Date: Dec. 22, 2005

(54) Isotropic glass-like conformal coatings and methods for applying same to non-planar substrate surfaces at microscopic levels

(75) Inventor: Jamie Knapp, Mendon, MA (US)

Correspondence Address: EDWARDS & ANGELL, LLP, P.O. BOX 55874, BOSTON, MA, 02205, US

(73) Assignee: Spectra-Physics Franklin, Inc.

(21) Appl. No.: 11/199,606

(22) Filed: Aug. 8, 2005

Related U.S. Application Data
(62) Division of application No. 10/782,042, filed on Feb. 18, 2004.

(51) Int. Cl. C23C 14/00; B32B 3/30

(52) U.S. Cl. 428/167; 427/523; 428/432; 428/702

(57) ABSTRACT

Coatings (e.g., thin film glass-like coatings) are deposited on a substrate via a reactive ion plating deposition process, which results in completely dense coatings that mimic the properties of bulk materials and that are fully conformal on all types of non-planar surfaces, even when the coatings have microscopic thicknesses.

### FIELD OF THE INVENTION

The present invention relates to coatings and techniques for applying such coatings, and, more particularly, to thin film conformal glass-like coatings and techniques for applying such coatings to non-planar substrate surfaces at the microscopic level.

### BACKGROUND OF THE INVENTION

It is known to coat an underlying object or material with one or more different coating materials in order to influence the properties and/or behavior of the underlying object or material. For example, it is known to apply or otherwise introduce oxide-based, glass-like thin film coatings onto the surfaces of underlying substrate materials made of a glass, metal, plastic or semiconductor.

In order to serve their intended functions (e.g., providing corrosion resistance, acting as chemical or thermal barriers, optical spectral filters, hermetic sealants, or electrical buffering layers and passivations), such coatings are required to possess/demonstrate certain minimum acceptable characteristics, including good adhesion to the underlying material or object, high density, surface hardness, purity, scratch resistance, lack of pinholes and inclusions, as well as compositional and thickness homogeneity and stability (e.g., the resistance of the coating to absorb moisture). Although many coating techniques are known, the various conventional coating techniques are all hampered by notable shortcomings and often do not possess minimum acceptable coating characteristics.

Electron beam evaporation is a suboptimal coating process because it relies upon line-of-sight technology, wherein substrates with non-planar surfaces cause physical shadowing and, in turn, result in coatings with poor uniformity. The process also requires elevated temperatures, which results in unstable coatings that are undesirably porous, and that tend to exhibit poor adhesion, especially on vertically oriented surfaces.

Sputtering (e.g., magnetron sputtering, RF sputtering, sputtering with or without plasma assist) and molecular beam epitaxy (MBE) are also line-of-sight coating processes that likewise suffer from physical shadowing and thus poor coating uniformity. Additionally, both sputtering and MBE coating processes tend to create/cause undesirably high coating stresses.

Chemical vapor deposition (CVD) coating techniques are accompanied by gas turbulence, which, in turn, inhibits (or altogether prevents) the application of truly uniform coatings, especially in sharp corners (e.g., corners having an angle of 90° or less). Also, coatings produced via CVD processes tend to be undesirably porous and soft. Like electron beam evaporation coating processes, CVD coating processes also are problematic in that they produce films that often exhibit poor adhesion, especially on vertically oriented surfaces. It should be noted that these problems are observed in both high and low pressure CVD processes onto both heated and unheated substrates.

Numerous problems also are observed/encountered when utilizing sol gel spin coating processes, including, but not limited to, the resultant coatings being porous, having inhomogeneities, particle inclusions, microcracks and/or voids, and exhibiting poor reproducibility and limited abrasion resistance. Moreover, coatings deposited by sol gel spin coating processes tend to be non-isotropic, especially in corner areas. Also, high surface tension of fluids during the sol gel process limits the geometry and sizes of the structured substrate.

In addition to the various shortcomings that are shared by or unique to these conventional coating processes, none of the processes is able to reliably provide a conformal coating (e.g., a thin film glass-like coating) atop/onto a non-planar surface at the microscopic level—that is, neither electron-beam evaporation, sputtering, MBE, CVD nor sol gel spin coating is able to produce/apply a coating having a microscopic thickness onto or atop a non-planar substrate surface such that the resulting coating possesses/exhibits uniform physical, chemical and optical properties in all directions. This is highly disadvantageous, especially in view of the increasing usage of and industrial focus upon ever-smaller objects and materials, which can likewise benefit from being coated with another material at the microscopic level.

Thus, a need exists for a process whereby a conformal coating (e.g., a thin film glass-like coating) can be reliably applied to any surface—even a non-planar surface—at microscopic levels, yet such that the various drawbacks that plague conventional coating processes are either eliminated or substantially minimized.

### SUMMARY OF THE INVENTION

The present invention meets these and other needs by providing techniques for producing conformal coatings. Such techniques are unexpectedly advantageous in that they are effective to produce fully conformal coatings (e.g., glass-like thin film coatings) on all types of non-planar surfaces (e.g., undulating surfaces, shallow or deep wells, stepped surfaces, and, in particular, gratings), even if the coating has a microscopic thickness.

As used herein, the term “microscopic” refers to a coating that comprises one or more layers, wherein the sum of the thicknesses of the coating layers is in the range of about 5 nanometers to 5000 nanometers, preferably about 10 nanometers to 1000 nanometers (nm). And the term “conformal” refers to a coating that has substantially uniform physical, chemical and optical properties in all directions.

The coatings of the present invention can be comprised of various materials, including, but not limited to, thin films of oxides (e.g., metal-oxides). By way of non-limiting example, the coating techniques of the present invention are effective to produce thin, conformal silicon dioxide (SiO₂) coatings that mimic the properties (e.g., hardness, density, durability, abrasion resistance) of bulk quartz. Such a SiO₂ coating is categorized as a “glass-like” coating, inasmuch as that term is used herein to refer to a coating that is comprised of one or more non-polymeric materials (e.g., one or more oxide materials, one or more nitride materials).

In accordance with the present invention, coatings are applied via a reactive ion plating deposition process, which results in completely dense coatings that do not spectrally shift upon exposure to varying temperature and humidity conditions. This process is in contrast to other ion-assisted processes (such as those described in U.S. Pat. Nos. 4,333,962, 4,448,802, 4,619,748, 5,211,759 and 5,229,570, each of which is incorporated by reference herein in its entirety) in which energized ions from an electron gun are directed toward the substrate but merely compact the previously vaporized, deposited coating material.

In accordance with an exemplary aspect of the present invention, plasma-supported reactive evaporation of the coating material(s) occurs in a vacuum (e.g., vaporizing the coating material by means of an electron beam under reduced pressure). The substrate(s) onto which the coating material is to be applied obtain a negative electrical charge, and the vaporized coating material—which is in the form of positively charged ions—is directed toward and then condensed on the target substrate(s). The resulting condensed coating has high energy (e.g., on the order of 20 to 100 eV) due to electromagnetic attraction between the ionized coating materials and the negatively biased substrates.

Not only are the optical, physical and chemical properties of coatings produced in accordance with the present invention uniform, but they also advantageously mimic those of bulk materials, even if the thickness of the coating is microscopic. This enables microscopic coatings to be applied to non-planar surfaces of substrates or objects (e.g., the inside of a hypodermic needle) on which it was it was previously thought to be impossible or highly difficult to deposit a conformal coating.

The coatings of the present invention also are beneficially low stress, isotropic and fully densified, have a uniform thickness that is independent of surface morphology, and are amorphous and structure-less in all directions. And because the coating processes of the present invention occur at room temperature, the processes are desirably applicable to a wide variety of temperature sensitive applications. The coating processes also exhibit excellent repeatability, and the resulting coatings are independent of surface morphology. In addition to these advantages, the coating processes of the present invention also do not suffer from the numerous disadvantages (e.g., porosity, lack of hardness, poor adhesion, microcracking, presence of inclusions, striations and/or voids) that plague conventional coating processes.

Various other aspects and embodiments of the present invention are discussed below.

### BRIEF DESCRIPTION OF THE DRAWINGS

For a fuller understanding of the nature and desired objects of the present invention, reference is made to the following detailed description, which is to be taken in conjunction with the accompanying drawing figures wherein like reference characters denote corresponding parts throughout the several views presented within the drawing figures, and wherein:

FIG. 1 is a schematic view of an apparatus for applying a coating in accordance with the present invention;

FIG. 2 is a schematic view of a substrate with non-planar surface features onto which a conformal coating has been applied in accordance with the present invention; and

FIGS. 3 and 4 are enlarged views of non-planar portions of substrates onto which a conventional coating has been applied.

### DETAILED DESCRIPTION OF THE INVENTION

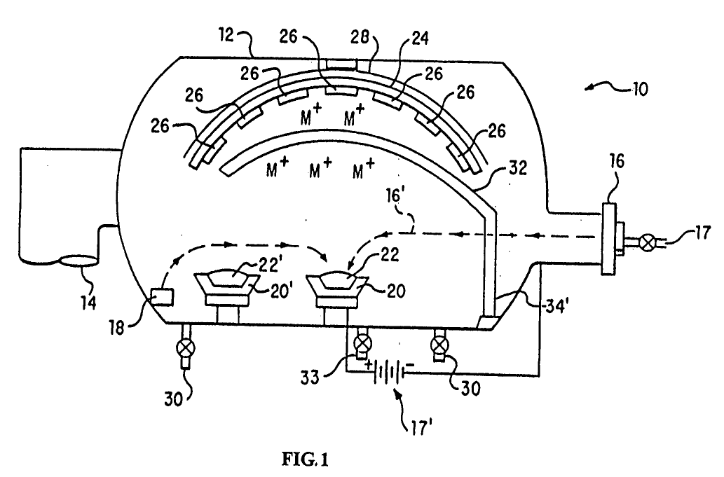

FIG. 1 illustrates an exemplary ion plating coating apparatus 10 as described in U.S. Pat. No. 6,139,968, the entirely of which is incorporated by reference herein. In accordance with the present invention, it has been discovered that the apparatus 10 of FIG. 1 is unexpectedly capable of producing conformal coatings onto non-planar substrate surfaces, even at microscopic levels.

Coating apparatus 10 includes an evacuatable coating vessel 12 and an evacuation/vacuum apparatus 14 that is in communication with, and that provides a vacuum to vessel 12. Apparatus 10 further includes a deposition plasma source 16 and one or more electron beam guns 18 for supplying electrons of energy directed towards one or more containment structures 20, 20′ that house the coating materials 22 and 22′. An exemplary coating apparatus 10 that is suitable for purposes of the present invention is the BAP 800 Batch Ion Plating System, which is commercially available from Balzers Aktiengesellschaft of Liechtenstein.

In accordance with a currently preferred embodiment of the present invention, each coating material 22, 22′ is a reagent that can form an oxide coating layer. By way of non-limiting example, coating materials 22, 22′ may be one or more of a silicon, titanium, aluminum, tantalum, hafnium, or zirconium reagent.

The containment structures 20, 20′ may have a range of shapes and sizes, and may be constructed of a number of suitable materials, wherein such choices can depend on such factors as the coating materials 22 that are to be contained therein. By way of non-limiting example, the containment structures 20, 20′ may be copper crucibles, each of which, according to a currently preferred embodiment of the present invention, includes a molybdenum liner.

The number of containment structures 20, 20′ that are included in coating apparatus 10 will depend on the composition of the coating layer(s) to be produced by the apparatus. For example, to apply conformal alternating coating layers of more than two materials onto a substrate (e.g., alternating layers of TiO₂ and SiO₂), one crucible will hold/house a first source chemical (e.g., a titanium source material), and a second crucible will hold/house a second source chemical (e.g., a silicon source material). In accordance with such an embodiment, the separate source chemicals will be separately activated by one or more electron guns 18.

The coating apparatus 10 further includes a substrate support structure 24, which is positioned opposite the containment structures 20, 20′ as illustrated in FIG. 1, and which (during the coating process) holds one or more substrates 26 onto which the coating materials 22, 22′ are to be deposited/applied as coating layers.

According to a currently preferred embodiment of the present invention, each of the one or more substrates 26 is cleaned prior to being loaded into the coating vessel 12 of the coating apparatus 10. By way of non-limiting example, such cleaning of the substrate(s) 26 can be accomplished mechanically (e.g. ultrasonically in non-ionic detergent) or chemically (e.g., through the use of one or more organic solvents).

A wide variety of substrates 26 may be employed in accordance with the present invention, including, by way of non-limiting example, glass substrates (e.g., optical color filter, glass, visible transmitting glass), metal substrates, plastic substrates, semiconductor substrates, and electronic device substrates (e.g., microelectronic wafers, detector devices).

Suitable optical color filter glass substrates include, but are not necessarily limited to, Schott glasses (such as those sold under the tradenames UG, BG, VB, GG, OG, RG and KG), Hoya color filter glasses (particularly UV transmitting and visible blocking glasses such as the material sold under the tradename of U-360), Sharp cut filters (e.g. Hoya's Y, 0, R, B, G), Cyan glass (e.g. Hoya's CM-500), IR blocking glass (e.g. Hoya's LP-15) and IR transmitting glasses (e.g. Hoya's R-72 and IR-80). Also, coating deposits of single-material and multi-material stabilized oxide glass may be made onto both ionically and colloidally colored glass substrates 26, wherein colloidally colored glasses generally come in two forms—those with reasonably good stain resistance, and those having significantly poorer stain/acid alkali resistance.

Exemplary visible transmitting glasses that can be utilized as substrates 26 in accordance with the present invention include, but are not necessarily limited to, crown glass, soda-lime float glass, natural quartz, synthetic fused silica, sapphire and Schott BK-7.

Exemplary semiconductor substrate materials for use as substrates 26 include, but are not necessarily limited to silicon, germanium, indium antimonide and HgCdTe.

Optionally, a heating device 28 may be utilized to heat the one or more substrates 26 to be coated, and one or more gas sources (which are depicted as dual feedlines 30 in FIG. 1) allow for the introduction of reactive gases during deposition of the coating material(s) 22. Optionally, a coating apparatus 10 of the present invention may contain one or more pre-treatment gas plasma sources 32 (to which gas is supplied by feedline 33). Plasma sources 32, if present, introduce a pre-treatment gas such as oxygen, argon or nitrogen into the coating vessel 12.

When utilizing the coating process of the present invention to apply coating layers onto one or more sensitive colored glass substrates 26, use of a pre-treatment plasma step prior to ion plating deposition can result in the subsequently applied ion plated coating layers having significantly improved physical properties, and, in particular, improved durability and substrate adherence. Therefore, it is currently preferred to include such a pre-treatment plasma step in accordance with such an embodiment of the present invention.

To deposit a coating layer in accordance with the present invention, coating vessel 12 is evacuated by vacuum system 14 to provide a base vacuum pressure to the coating vessel of less than about 3×10⁻⁶ mbar. The vacuum system 14 can be any system currently, formerly or hereafter known to one or ordinary skill the art, e.g., an oil diffusion pump with a Roots Blower.

One or more electron beam guns 18 of deposition plasma source 16 are employed to supply electrons of energy during the coating process. In use, the electron beam gun(s) 18 direct an intense electron beam into the containment structure(s) 20, 20′ to vaporize the coating material(s) 22 and 22′ contained therein. According to a currently preferred embodiment of the present invention, two 270° electron beam guns are employed.

Deposition plasma source 16 also generally includes a heated tantalum filament and a gas inlet 17. The plasma source 16 is connected to the electrically conductive containment structure(s) 20, 20′ through a low voltage, high current power supply 17′.

By way of non-limiting example, and as shown in FIG. 1, the electrically insulated substrate support structure 24 can be a rotating, elongate, dome-shaped structure that is suspended from the ceiling of the coating vessel 12 as is generally known in the art. It should be noted, however, that the substrate support structure 24 may be differently configured; for example, it may have a substantially flat surface or it may be substantially cone-shaped.

As a result of the deposition plasma discharge that is operated during the coating process, substrates 26 that are positioned on the support structure 24 become negatively self-biased and the vaporized coating material (which is denoted by M+ in FIG. 1) that is activated by the deposition plasma becomes highly energetic, ionized and chemically reactive. The energized material M+ is attracted to the one or more substrates 26 via electromagnetic coulomb attraction, after which coating/film deposition occurs.

It should be noted, however, that the deposition plasma procedure may be commenced immediately after the gas plasma pretreatment is completed, without vacuum interruption.

According to a currently preferred embodiment of the present invention, the coating apparatus 10 further includes a heating device 28 for heating the substrate(s) to be coated. By way of non-limiting example, the heating device may be a Calrod heater, which is positioned above the substrates as generally shown in FIG. 1, and/or one or more quartz lamps. The coating apparatus 10 of the present invention may further include one or more additional auxiliary devices (e.g., auxiliary coils for the production of magnetic fields, etc.), which are generally known in the art.

As discussed above, the coating apparatus also contains a reactive gas source, which is illustrated as a plurality of gas feedlines 30 in FIG. 1. The depicted gas feedlines 30 discharge one or more reactive gases at a position proximate to the containment structures 20, 20′ such that an effective density of reactive gas can mix and react with material vaporized from the containment structure(s) during the ion plating coating step.

A variety of gases (e.g., oxygen, nitrogen), aliphatic and aromatic hydrocarbons (e.g., acetylene, methane, ethane, propylene, benzene, etc.) and/or other airborne materials can be introduced into the coating vessel 12 through the reactive gas feedline(s) 30, wherein the specific choice of gas(es)/airborne material(s) depends on factors such as the coating that is to be deposited. For example, when depositing a coating that is comprised of titanium oxide, silicon dioxide, aluminum oxide and/or other oxygen-containing layers, oxygen will be supplied through one or more feedlines 30 to react with the one or more source chemicals/metals that are vaporized from containment structure 20 or 20′.

Additionally, a mixture of one or more reactive gases may be introduced into coating vessel 12 to produce a coating layer of a desired composition onto the one or more substrate(s) 26. For example, nitrogen and acetylene may be simultaneously supplied through separate lines 30 to provide a carbonitride-type coating on the substrate(s) 26. Coating layers having other compositions also may be applied, as will be appreciated by those of ordinary skill in the art.

### EXAMPLE

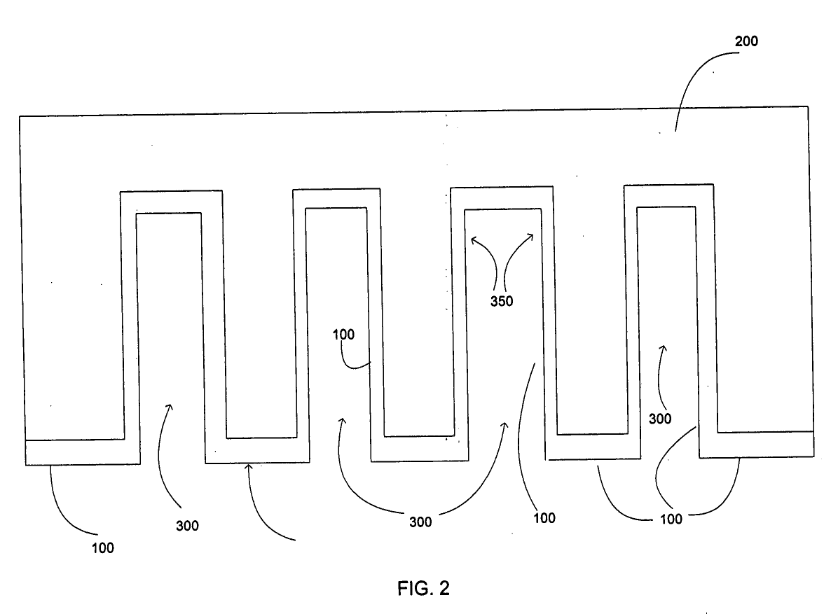

As shown in FIG. 2, a conformal ion-plated silicon dioxide coating 100 having a physical thickness of 450 nm was uniformly deposited at room temperature upon a structured transparent borosilicate glass substrate 200. The thickness of the glass substrate 200 was about 2 mm, and the glass substrate was structured to include a plurality of microscopic non-planar areas 300. The length, width and depth of each non-planar area/surface 300 measured about 50 microns.

As evaluated by scanning electron microscopy, the resultant glass-like silicon dioxide coating was thoroughly conformal, with uniform coverage even in the sharp interior corners 350 of each non-planar area/surface 300. Moreover, the physical structure of the resulting silicon dioxide coating 100 was amorphous and fully densified, and mimicked the optical, physical and chemical characteristics of pure bulk quartz.

The ion plating deposition conditions for application of such a silicon dioxide coating 100 may generally vary within a range of values, and may be readily determined empirically based on the present disclosure.

More specifically, for application of a thin film coating layer 100 of SiO₂ onto a structured substrate 200, silicon is loaded into copper crucible containment structure 20′ of coating vessel 12. If a pre-treatment plasma step is employed, the pre-treatment plasma gas is oxygen or argon. A glow discharge rod 32 is used to provide a pre-treatment plasma step voltage of about 4.5 kV, a current of about 350 mA, and a duration of glow of about 30 to 45 minutes. Following such a pre-treatment step, or directly after applying the desired vacuum to vessel 12 if a pre-treatment step is not carried out, the deposition plasma gas pressure within plasma source is 2.8 mbar, the plasma voltage is in the range of about 55 to 60 volts, the plasma current is in the range of about 55 to 60 amps, the anode-to-ground voltage is about 40 volts, the plasma filament current is about 110 amps, the reactive gas is oxygen (introduced through feedline(s) 30 in FIG. 1), and the reactive gas pressure is about 1×10⁻³ mbar within the coating vessel 12. The electron beam gun(s) 18 for reagent evaporation can be operated at a high voltage of 10 kV, an emission of 400 mA and at a rate of 0.5 nm/second.

Thus, the following conditions/parameters represent those that are currently preferred when depositing a coating 100 of silicon dioxide onto a substrate 200 having microscopic non-planar areas 300. Deposition conditions/parameters for depositing other materials generally will be the same or similar to these conditions.

| | | E-beam | | | | | |
|---|---|---|---|---|---|---|---|
| Coating | Crucible | high | | Deposition | | | |
| Material | material | voltage | Emission | Rate | Ramp 1 | Ramp 2 | Ramp 3 |
| Silicon | Copper | 10 kV | 400 mA | 0.5 nm/s | 20 s/38% | 40 s/46% | 40 s/51% |

| Hold | Arc | Arc | Anode-to | | |
|---|---|---|---|---|---|
| Power | Current | Voltage | Ground Voltage | Plasma Gas | Reaction Gas |
| 22.0% | 55 A | 55 V | 35 V | Argon at | Oxygen at 1.0 × 10⁻³ mbar |
| | | | | 2.8 mbar | within coating |
| | | | | within | vessel |
| | | | | plasma | |

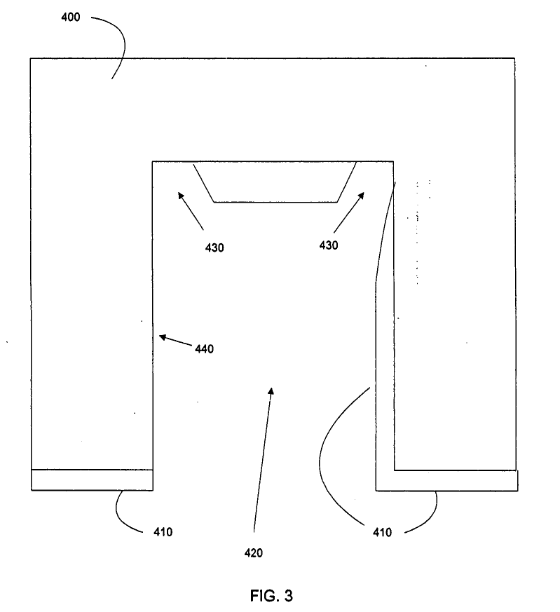

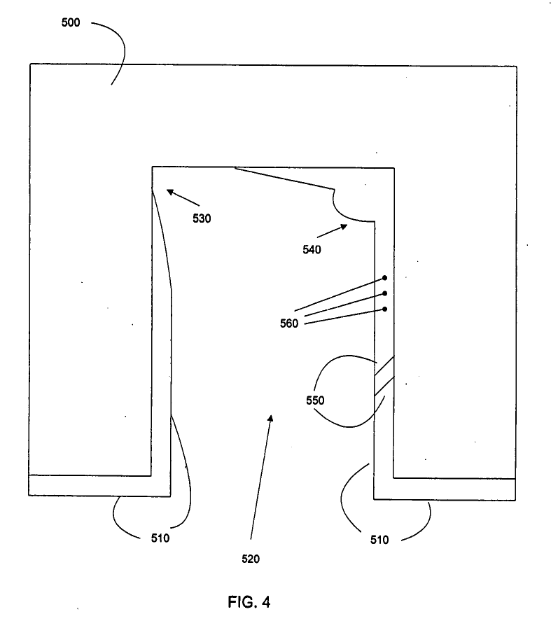

In contrast to FIG. 2, which depicts the results of a successful application of a conformal coating 100 onto microscopic non-planar areas 300 of a substrate 200 in accordance with the present invention, FIGS. 3 and 4 depict some of the drawbacks/problems that occur when attempting to apply a conformal coating onto non-planar areas of substrates via conventional coating techniques.

Like FIG. 2, FIG. 3 depicts a substrate 400, wherein a coating 410 has been applied onto at least one a non-planar area/surface 420 of the substrate. However, the coating 410 is not conformal inasmuch as voids (i.e., areas in which either too little or entirely no coating was applied) are present in the corners 430 and on a sidewall 440 of the microscopic non-planar area 420. Voids in corners 430 tend to occur via a conventional CVD coating process due to gas turbulence that accompanies the process, whereas voids at sidewalls 440 are due to the shadowing that accompanies line-of-sight coating processes such as electron beam evaporation, molecular beam epitaxy and sputtering. Additional problems/defects that are not shown in FIG. 3 but that tend to be present in or exhibited by coatings 410 produced by these processes include, but are not limited to, the coatings exhibiting/including porosity, softness, inclusions, microcracks, poor adherence, low density, and excessive stress. The presence of such defects/problems prevents these coatings 410 from being successfully utilized as chemical and thermal barriers, hermetic seals or electrical passivation.

Also like FIG. 2, FIG. 4 depicts a substrate 500, wherein a coating 510 has been applied onto a non-planar area/surface 520 of the substrate via a sol gel spin coating technique. Among the problems/defects that can occur via this technique and that would render the coating 510 non-conformal are (a) the presence of one or more voids (i.e., one or more areas in which either too little or entirely no coating was applied) in one or more corners 530 of the non-planar area 520, (b) an excess of coating in one or more corners 540 of the non-planar area, (c) the presence of striations 550 in the non-planar area, and/or (d) the presence of particle inclusions 560 in the non-planar area. Other problems/defects that are not shown in FIG. 4 but that tend to be present in or exhibited by coatings 510 produced by sol gel spin coating processes include, but are not limited to, the coatings exhibiting/including porosity, softness, microcracks, poor adherence, poor reproducibility, and low density.

Although the present invention has been described herein with reference to details of currently preferred embodiments, it is not intended that such details be regarded as limiting the scope of the invention, except as and to the extent that they are included in the following claims—that is, the foregoing description of the present invention is merely illustrative, and it should be understood that variations and modifications can be effected without departing from the scope or spirit of the invention as set forth in the following claims. Moreover, any document(s) mentioned herein are incorporated by reference in their entirety, as are any other documents that are referenced within the document(s) mentioned herein.

1-13. (canceled)

14. A substrate, comprising:
at least one non-planar surface coated with a glass-like coating, wherein the glass-like coating includes at least one coating layer, and wherein each of the at least one coating layer is conformal throughout each of the at least one non-planar surface of the substrate.

15. The substrate of claim 14, wherein each of the at least one coating layer has a predetermined thickness, and wherein the sum of the thicknesses of each of the at least one coating layer is in the range of about 5 nanometers to 5000 nanometers.

16. The substrate of claim 15, wherein the sum of the thicknesses of each of the at least one coating layer is in the range of about 10 nanometers to 1000 nanometers.

17. The substrate of claim 14, wherein the substrate is selected from the group consisting of a glass substrate, a metal substrate, a plastic substrate, a semiconductor substrate, and an electronic device substrate.

18. The substrate of claim 14, wherein each of the at least one non-planar surface is selected from the group consisting of at least grating, at least one undulating surface, at least one well, and at least one stepped surface.

19. The substrate of claim 14, wherein the at least one coating layer is a thin film.

20. The substrate of claim 19, wherein the at least one coating layer is an oxide thin film.

21. The substrate of claim 20, wherein the at least one coating layer is a metal oxide thin film.

22. The substrate of claim 14, wherein the coating is comprised of a plurality of coating layers.
